(19) United States
(12) Patent Application Publication
(10) Pub. No.: US 2015/0198839 A1
(43) Pub. Date: Jul. 16, 2015

(54) DISPLAY DEVICE AND MANUFACTURING METHOD THEREOF

(71) Applicant: Samsung Display Co., Ltd., Yongin-City (KR)

(72) Inventors: You Young JIN, Suwon-si (KR); Seok-Joon HONG, Seongnam-si (KR); Woo Jae LEE, Yongin-si (KR)

(73) Assignee: Samsung Display Co., Ltd., Yongin-City (KR)

(21) Appl. No.: 14/295,048

(22) Filed: Jun. 3, 2014

(30) Foreign Application Priority Data
Jan. 16, 2014 (KR) 10-2014-0005715

(51) Int. Cl. G02F 1/1333; H01L 27/12; G02F 1/1362; G02F 1/1341; G02F 1/1368; G02F 1/1343

(52) U.S. Cl. CPC G02F 1/133377; G02F 1/1368; G02F 1/13439; G02F 1/136286; G02F 1/1341; H01L 27/1262

(57) ABSTRACT

An exemplary embodiment provides a manufacturing method of a display device as follows. A thin film transistor is formed on a substrate. A pixel electrode connected to the thin film transistor is formed. A first barrier layer is formed on the pixel electrode. A sacrificial layer is formed on the first barrier layer. A second barrier layer is formed on the sacrificial layer. A common electrode is formed on the sacrificial layer. A roof layer is formed on the common electrode. The common electrode and the roof layer are patterned to expose a portion of the sacrificial layer. The sacrificial layer is removed to form a microcavity between the pixel electrode and the common electrode. The first barrier layer and the second barrier layer are removed. A liquid crystal material is injected inside the microcavity to form a liquid crystal layer. An encapsulation layer is formed to cover a portion where the microcavity is exposed to seal the microcavity.

### CROSS-REFERENCE TO RELATED APPLICATION

This application claims priority to and the benefit of Korean Patent Application No. 10-2014-0005715 filed in the Korean Intellectual Property Office on Jan. 16, 2014, the entire contents of which are incorporated herein by reference.

### BACKGROUND

(a) Technical Field

The present application relates to a display device and a manufacturing method thereof, and more particularly, to a display device and a manufacturing method thereof, which can remove films that are deformed in a process.

(b) Description of the Related Art

A liquid crystal display as one of flat panel display devices that are being widely used includes two display panels, wherein field generating electrodes such as a pixel electrode and a common electrode are formed with a liquid crystal layer interposed therebetween. The liquid crystal display generates an electric field in the liquid crystal layer by applying a voltage to the field generating electrodes to determine orientations of liquid crystal molecules of the liquid crystal layer and control polarization of incident light, thereby displaying an image.

The two display panels constituting the liquid crystal display may be formed of a thin film transistor array panel and an opposing display panel. In the thin film transistor array panel, a gate line transferring a gate signal and a data line transferring a data signal are formed to cross each other, and a thin film transistor connected to the gate line and the data line, a pixel electrode connected to the thin film transistor, and the like may be formed. A light blocking member, a color filter, a common electrode, and the like may be formed in the opposing display panel. If necessary, the light blocking member, the color filter, and the common electrode may be formed in the thin film transistor array panel.

However, in a liquid crystal display in the related art, two substrates are essentially used and constituent elements are formed on the two substrates, so that there are problems in that the display device is heavy and thick, a cost thereof is high, and a process time is long.

The above information disclosed in this Background section is only for enhancement of understanding of the background and therefore it may contain information that does not form the prior art that is already known in this country to a person of ordinary skill in the art.

### SUMMARY

Embodiments have been made in an effort to provide a display device and a manufacturing method thereof, which can decrease weight, thickness, cost, and process time by manufacturing the display device using one substrate.

Further, embodiments have been made in an effort to provide a display device and a manufacturing method thereof, which can remove deformed films in a process.

An exemplary embodiment provides a display device including: a substrate; a thin film transistor; a pixel electrode; a common electrode; a roof layer; a liquid crystal layer; and an encapsulation layer. The thin film transistor is on the substrate. The pixel electrode is connected to the thin film transistor. The common electrode is on the pixel electrode to be spaced apart from the pixel electrode with a plurality of microcavities comprising a microcavity interposed therebetween. The roof layer is on the common electrode. The liquid crystal layer fills the microcavity. The encapsulation layer is on the roof layer to seal the microcavity, wherein the common electrode is positioned at an edge of the microcavity and has a step shape.

The common electrode may cover a top surface and a side surface of the microcavity, and a portion of the common electrode which covers the side surface of the microcavity may have a step shape.

The microcavities may be disposed in a matrix shape, and the display device may further include a first valley positioned between microcavities adjacent to each other in a column direction, and a second valley positioned between microcavities adjacent to each other in a row direction.

The common electrode may be further on the second valley.

A portion of the common electrode which is adjacent to the second valley may be in a step shape.

The display device may further include an insulating layer on the thin film transistor, and the common electrode may be immediately on the insulating layer in the second valley.

An exemplary embodiment provides a manufacturing method of a display device as follows. A thin film transistor is formed on a substrate. A pixel electrode connected to the thin film transistor is formed. A first barrier layer is formed on the pixel electrode. A sacrificial layer is formed on the first barrier layer. A second barrier layer is formed on the sacrificial layer. A common electrode is formed on the sacrificial layer. A roof layer is formed on the common electrode. The common electrode and the roof layer are patterned to expose a portion of the sacrificial layer. The sacrificial layer is removed to form a microcavity between the pixel electrode and the common electrode. The first barrier layer and the second barrier layer are removed. A liquid crystal material is injected inside the microcavity to form a liquid crystal layer. An encapsulation layer is formed to cover a portion where the microcavity is exposed to seal the microcavity.

A plurality of microcavities including the microcavity may be disposed in a matrix shape, a first valley may be positioned between microcavities adjacent to each other in a column direction, and a second valley may be positioned between microcavities adjacent to each other in a row direction.

The manufacturing method may further include patterning the first barrier layer and the second barrier layer after the second barrier layer is formed.

Portions of the first barrier layer and the second barrier layer, which are positioned at the second valley, may be removed in the patterning of the first barrier layer and the second barrier layer.

The common electrode may be further formed on the second valley.

A portion of the common electrode which is adjacent to the second valley may be formed in a step shape.

The manufacturing method may further include forming an insulating layer on the thin film transistor, and forming the common electrode immediately on the insulating layer in the second valley.

The common electrode may cover a top surface and a side surface of the microcavity, and a portion of the common electrode which covers the side surface of the microcavity may be formed to have a step shape.

The first barrier layer and the second barrier layer may be removed by using a wet etching method in the removing of the first barrier layer and the second barrier layer.

The pixel electrode and the common electrode may not be removed in the process of removing the first barrier layer and the second barrier layer.

Each of the first barrier layer and the second barrier layer may include copper.

Each of the pixel electrode and the common electrode may include indium tin oxide (ITO) or indium zinc oxide (IZO).

The first barrier layer may be formed to have a thickness that is thinner than that of the pixel electrode.

The second barrier layer may be formed to have a thickness that is thinner than that of the common electrode.

As described above, the display device and the manufacturing method thereof in accordance with the exemplary embodiments have the following effects.

According to the display device and the manufacturing method thereof in accordance with the exemplary embodiments, it is possible to reduce weight, thickness, cost, and processing time by manufacturing the display device by using one substrate.

Further, it is possible to easily remove deformed films caused by deformation of the sacrificial film by forming the barrier layers on the pixel electrode and below the common electrode, and removing the sacrificial layer and then removing the barrier layers.

### BRIEF DESCRIPTION OF THE DRAWINGS

FIG. 1 is a top plan view illustrating a display device in accordance with an exemplary embodiment.

FIG. 2 is an equivalent circuit diagram of one pixel of the display device in accordance with the exemplary embodiment.

FIG. 3 is a layout view illustrating a part of the display device in accordance with the exemplary embodiment.

FIG. 4 is a cross-sectional view of the display device in accordance with the exemplary embodiment taken along line IV-IV of FIG. 3.

FIG. 5 is a cross-sectional view illustrating the display device in accordance with the exemplary embodiment taken long line V-V of FIG. 3.

FIGS. 6, 7, 8, 9, 10, 11, 12, 13 are stepwise cross-sectional views illustrating a manufacturing method of the display device in accordance with the exemplary embodiment.

### DETAILED DESCRIPTION OF THE EMBODIMENTS

The inventive concept will be described more fully hereinafter with reference to the accompanying drawings, in which exemplary embodiments are shown. As those skilled in the art would realize, the described embodiments may be modified in various different ways, all without departing from the spirit or scope of the inventive concept.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

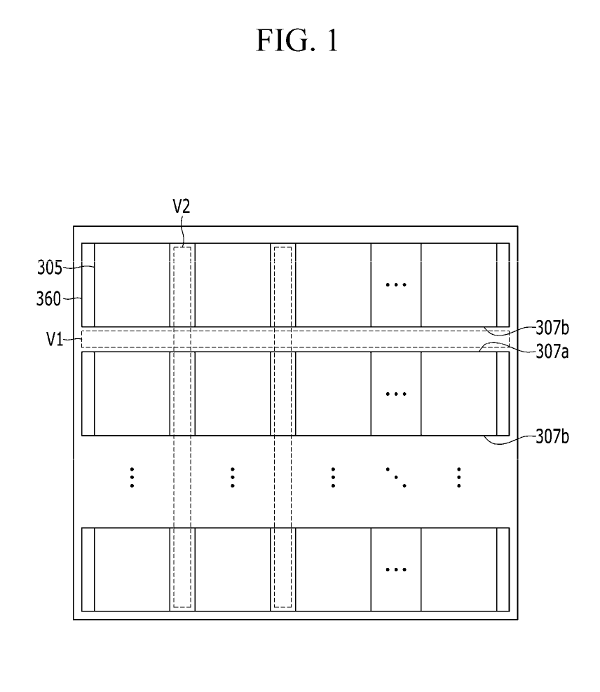

A display device in accordance with an exemplary embodiment will be briefly described with reference to FIG. 1.

FIG. 1 is a top plan view illustrating the display device in accordance with the exemplary embodiment.

The display device according to the exemplary embodiment includes a substrate 110 formed of a material such as glass and plastic.

Microcavities 305 covered by roof layers 360 are formed on the substrate 110. The roof layers 360 are extended in a row direction, and a plurality of microcavities 305 are formed under one roof layer 360.

The microcavities 305 may be arranged in a matrix form, and a first valley V1 is positioned between the vertically adjacent microcavities 305, while a second valley V2 is positioned between the horizontally adjacent microcavities 305.

A plurality of roof layers 360 may be separated from each other with the first valley V1 interposed therebetween. The microcavities 305 may not be covered by the roof layer 360 but may be exposed to the outside at portions which are in contact with the first valley V1. These portions are referred to as injection holes 307a and 307b.

The injection holes 307a and 307b are formed at both edges of the each microcavity 305. The injection holes 307a and 307b include a first injection hole 307a and a second injection hole 307b. The first injection hole 307a is formed so as to extend to and expose a lateral surface of a first edge of the microcavity 305, while the second injection hole 307b is formed so as to extend to and expose a lateral surface of a second edge of the microcavity 305. The lateral surface of the first edge and the lateral surface of the second edge of the microcavity 305 face each other.

Each roof layer 360 is formed to be spaced apart from the substrate 110 between the adjacent second valleys V2 to form the microcavity 305. That is, the roof layer 360 is formed so as to cover the remaining lateral surfaces, except for the lateral surfaces of the first edge and the second edge in which the injection holes 307a and 307b are formed.

The aforementioned structure of the display device according to the exemplary embodiment is just an example, and various modifications are feasible. For example, a disposition form of the microcavity 305, the first valley V1, and the second valley V2 may be changed, the plurality of roof layers 360 may be connected to each other in the first valley V1, and a portion of each roof layer 360 may be formed to be spaced apart from the substrate 110 in the second valley V2 to connect adjacent microcavities 305 to each other.

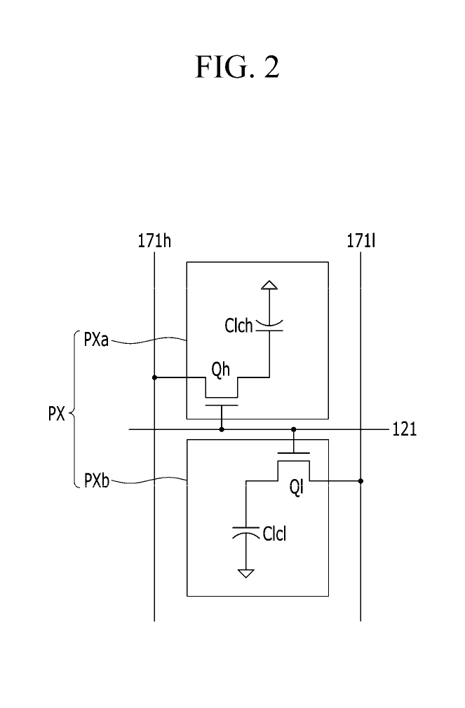

Hereinafter, one pixel of the display device in accordance with the exemplary embodiment will be briefly described with reference to FIG. 2.

FIG. 2 is an equivalent circuit diagram of one pixel of the display device in accordance with the exemplary embodiment.

The display device of the present exemplary embodiment includes a plurality of signal lines 121, 171h, and 171l, and a plurality of pixels PX connected to the plurality of signal lines 121, 171h, and 171l. The plurality of pixels PX may be arranged in a matrix form including a plurality of pixel rows and a plurality of pixel columns.

Each pixel PX may include a first sub-pixel PXa and a second sub-pixel PXb. The first sub-pixel PXa and the second sub-pixel PXb may be vertically disposed. In this case, the first valley V1 may be positioned in a direction of a pixel row between the first sub-pixel PXa and the second sub-pixel PXb, and the second valley V2 may be positioned between the plurality of pixel columns.

The signal lines 121, 171h, and 171l include a gate line 121 for transmitting a gate signal, and a first data line 171h and a second data line 171l for transmitting different data voltages.

The display device in accordance with the exemplary embodiment includes a first switching element Qh connected to the gate line 121 and the first data line 171h, and a second switching element Ql connected to the gate line 121 and the second data line 171l.

A first liquid crystal capacitor Clch connected with the first switching element Qh is formed in the first sub-pixel PXa, and a second liquid crystal capacitor Clcl connected with the second switching element Ql is formed in the second sub-pixel PXb.

A first terminal of the first switching element Qh is connected with the gate line 121, a second terminal thereof is connected with the first data line 171h, and a third terminal thereof is connected to the first liquid crystal capacitor Clch.

A first terminal of the second switching element Ql is connected with the gate line 121, a second terminal thereof is connected with the second data line 171l, and a third terminal thereof is connected to the second liquid crystal capacitor Clcl.

An operation of the liquid crystal display in accordance with the exemplary embodiment will now be described. When a gate-on voltage is applied to the gate line 121, the first switching element Qh and the second switching element Ql connected to the gate line 121 enter a turn-on state, and the first and second liquid crystal capacitors Clch and Clcl are charged by different data voltages transmitted through the first and second data lines 171h and 171l. The data voltage transmitted by the second data line 171l is lower than the data voltage transmitted by the first data line 171h. Accordingly, the second liquid crystal capacitor Clcl is charged with a lower voltage than that of the first liquid crystal capacitor Clch, thereby improving side visibility.

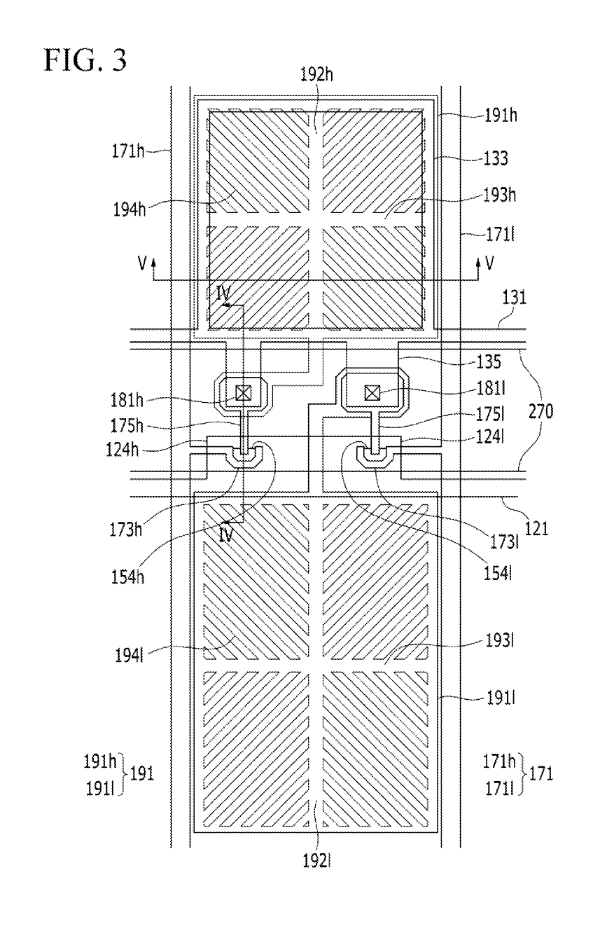

Hereinafter, a structure of one pixel of the liquid crystal display in accordance with the exemplary embodiment will be described with reference to FIGS. 3 to 5.

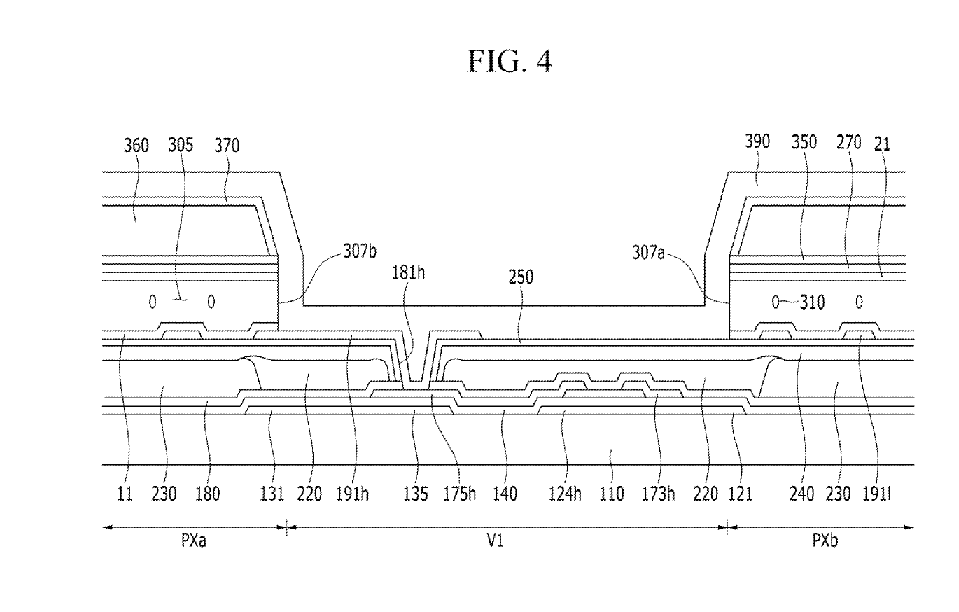

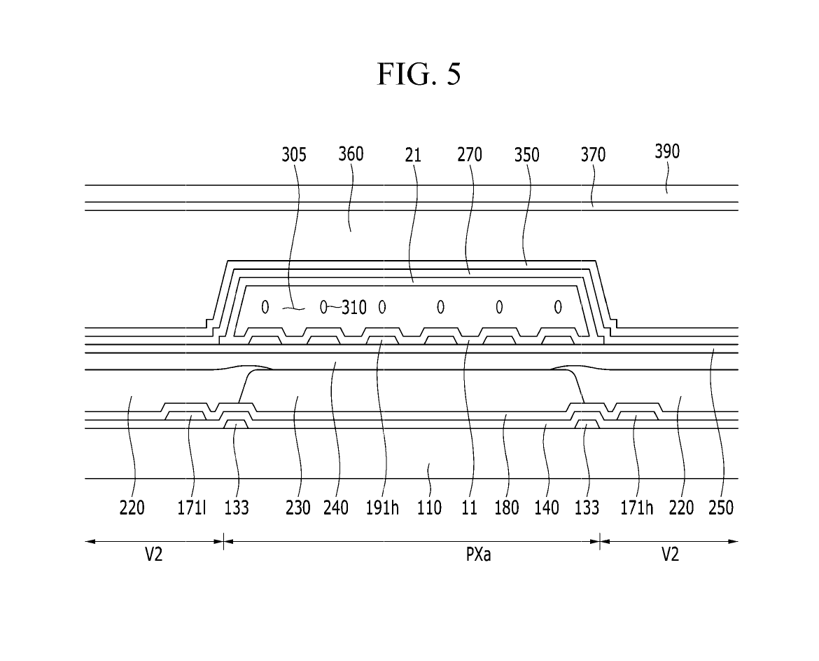

FIG. 3 is a layout view illustrating a part of the display device in accordance with the exemplary embodiment, and FIG. 4 is a cross-sectional view of the display device in accordance with the exemplary embodiment taken along line IV-IV of FIG. 3. FIG. 5 is a cross-sectional view illustrating the display device in accordance with the exemplary embodiment taken long line V-V of FIG. 3.

Referring to FIGS. 3 to 5, the gate line 121 and a first gate electrode 124h and a second gate electrode 124l protruding from the gate line 121 are formed on the substrate 110.

The gate line 121 mainly extends in a horizontal direction, and transmits a gate signal. The gate line 121 is positioned between the two microcavities 305 which are adjacent in a column direction. That is, the gate line 121 is positioned at the first valley V1. The first gate electrode 124h and the second gate electrode 124l upwardly protrude in a plane view at an upper side of the gate line 121. The first gate electrode 124h and the second gate electrode 124l are connected to each other to form one protrusion. However, the inventive concept is not limited thereto, and the protruding form of the first gate electrode 124h and the second gate electrode 124l may be variously modified.

A storage electrode line 131 and storage electrodes 133 and 135 protruding from the storage electrode line 131 may be further formed on the substrate 110.

The storage electrode line 131 extends in a direction parallel to the gate line 121, and is formed to be spaced apart from the gate line 121. A predetermined voltage may be applied to the storage electrode line 131. The storage electrode 133 protruded on the storage electrode line 131 is formed to enclose an edge of the first subpixel PXa. The storage electrode 135 protruded under the storage electrode line 131 is formed to be adjacent to the first gate electrode 124h and the second gate electrode 124l.

A gate insulating layer 140 is formed on the gate line 121, the first gate electrode 124h, the second gate electrode 124l, the storage electrode line 131, and the storage electrode 135. The gate insulating layer 140 may be formed of an inorganic insulating material, such as a silicon nitride (SiNx) and a silicon oxide (SiOx). Further, the gate insulating layer 140 may be formed of a single layer or a multilayer.

A first semiconductor 154h and a second semiconductor 154l are formed on the gate insulating layer 140. The first semiconductor 154h may be positioned on the first gate electrode 124h, and the second semiconductor 154l may be positioned on the second gate electrode 124l. The first semiconductor 154h may be elongated under the first data line 171h, and the second semiconductor 154l may be elongated under the second data line 171l. The first semiconductor layer 154h and the second semiconductor 154l may be formed of amorphous silicon, polycrystalline silicon, a metal oxide, or the like.

An ohmic contact member (not illustrated) may be formed on each of the first semiconductor 154h and the second semiconductor 154l. The ohmic contact members may be made of a silicide or a material such as n+ hydrogenated amorphous silicon on which an n-type impurity is doped at a high concentration.

The first data line 171h, the second data line 171l, a first source electrode 173h, a first drain electrode 175h, a second source electrode 173l, and a second drain electrode 175l are formed on the first semiconductor 154h, the second semiconductor 154l, and the gate insulating layer 140.

The first data line 171h and the second data line 171l, collectively or individually sometimes referred to as a data line 171, transfer a data signal, and mainly extend in a vertical direction to cross the gate line 121 and the storage electrode line 131. The data line 171 is positioned between the two microcavities 305 which are adjacent in the row direction. That is, the data line 171 is positioned at the second valley V2.

The first data line 171h and the second data line 171l transmit different data voltages. The data voltage transmitted by the second data line 171l is lower than the data voltage transmitted by the first data line 171h.

The first source electrode 173h is formed so as to upwardly protrude from the first gate electrode 124h from the first data line 171h, and the second source electrode 173l is formed to upwardly protrude from the second gate electrode 124l from the second data line 171l. Each of the first drain electrode 175h and the second drain electrode 175l has one wide end portion and the other rod-shaped end portion. The wide end portions of the first drain electrode 175h and the second drain electrode 175l overlap the storage electrode 135 downwardly protruding from the storage electrode line 131. Each of the rod-shaped end portions of the first drain electrode 175h and the second drain electrode 175l is partially surrounded by the first source electrode 173h and the second source electrode 173l.

The first and second gate electrodes 124h and 124l, the first and second source electrodes 173h and 173l, and the first and second drain electrodes 175h and 175l form first and second thin film transistors (TFT) Qh and Ql together with the first and second semiconductors 154h and 154l, and channels of the thin film transistors Qh and Ql are formed in the semiconductors 154h and 154l between the source electrodes 173h and 173l and the drain electrodes 175h and 175l, respectively.

A passivation layer 180 is formed on the first data line 171h, the second data line 171l, the first source electrode 173h, the first drain electrode 175h, the first semiconductor 154h exposed between the first source electrode 173h and the first drain electrode 175h, the second source electrode 173l, the second drain electrode 175l, and the second semiconductor 154l exposed between the second source electrode 173l and the drain electrode 175l. The passivation layer 180 may be formed of an organic insulating material or an inorganic insulating material, and may be formed of a single layer or a multilayer.

A color filter 230 is formed in each pixel PX on the passivation layer 180.

Each color filter 230 may display any one of primary colors, such as three primary colors of red, green, and blue. The color filter 230 is not limited to the three primary colors of red, green, and blue, and may display cyan, magenta, yellow, and white-based colors. The color filter 230 may not be formed at the first valley V1.

A light blocking member 220 is formed in a region between adjacent color filters 230. The light blocking member 220 is formed on a boundary of the pixel PX and the thin film transistor to prevent light leakage. That is, the light blocking member 220 may be formed in the first valley V1 and the second valley V2. The color filter 230 and the light blocking member 220 may be overlapped with each other in a partial region.

A first insulating layer 240 may be further formed on the color filter 230 and the light blocking member 220. The first insulating layer 240 may be formed of an organic insulating material, and may serve to planarize the color filters 230.

A second insulating layer 250 may be further formed on the first insulating layer 240. The second insulating layer 250 may be formed of an inorganic insulating material, and may serve to protect the color filter 230 and the first insulating layer 240.

A first contact hole 181h that extends to and through which the wide end portion of the first drain electrode 175h is exposed and a second contact hole 181l that extends to and through which the wide end portion of the second drain electrode 175l is exposed are formed in the passivation layer 180, the first insulating layer 240, and the second insulating layer 250.

A pixel electrode 191 is formed on the second insulating layer 250. The pixel electrode 191 may be formed of a transparent metal material, such as indium-tin oxide (ITO) and indium-zinc oxide (IZO).

The pixel electrode 191 includes a first subpixel electrode 191h and a second subpixel electrode 191l which are separated from each other with the gate line 121 and the storage electrode line 131 interposed therebetween. The first subpixel electrode 191h and the second subpixel electrode 191l are disposed on and under the pixel PX based on the gate line 121 and the storage electrode line 131. That is, the first sub-pixel electrode 191h and the second sub-pixel electrode 191l are separated from each other with the first valley V1 interposed therebetween, and the first sub-pixel electrode 191h is positioned in the first sub-pixel PXa and the second sub-pixel electrode 191l is positioned in the second sub-pixel PXb.

The first sub-pixel electrode 191h is connected to the first drain electrode 175h through the first contact hole 181h, and the second sub-pixel electrode 191l is connected to the second drain electrode 175l through the second contact hole 181l. Accordingly, when the first thin film transistor Qh and the second thin film transistor Ql are in an on-state, the first sub-pixel electrode 191h and the second sub-pixel electrode 191l receive different data voltages from the first drain electrode 175h and the second drain electrode 175l, respectively. An electric field may be formed between the pixel electrode 191 and a common electrode 270.

A general shape of each of the first sub-pixel electrode 191h and the second sub-pixel electrode 191l is a quadrangle, and the first sub-pixel electrode 191h and the second sub-pixel electrode 191l include cross-shaped stem portions formed by horizontal stem portions 193h and 193l and vertical stem portions 192h and 192l crossing the horizontal stem portions 193h and 193l. Further, each of the first sub-pixel electrode 191h and the second sub-pixel electrode 191l includes a plurality of micro-branch portions 194h and 194l.

The pixel electrode 191 is divided into four sub-regions by horizontal stem portions 193h and 193l and vertical stem portions 192h and 192l. The micro-branch portions 194h and 194l obliquely extend from the horizontal stem portions 193h and 193l and the vertical stem portions 192h and 192l, and the extension direction may form an angle of approximately 45° or 135° with the gate line 121 or the horizontal stem portions 193h and 193l. Further, the directions in which the micro-branch portions 194h and 194l in two adjacent sub-regions extend may be orthogonal to each other.

In the present exemplary embodiment, the first sub-pixel electrode 191h and the second sub-pixel electrode 191l may further include outer stem portions surrounding outer sides of the first sub-pixel PXa and the second sub-pixel PXb, respectively.

The disposition form of the pixel, the structure of the thin film transistor, and the shape of the pixel electrode described above are one example, the inventive concept is not limited thereto, and various modifications are feasible.

The common electrode 270 is formed on the pixel electrode 191 so as to be spaced apart from the pixel electrode 191 by a predetermined distance. The microcavity 305 is formed between the pixel electrode 191 and the common electrode 270. That is, the microcavity 305 is surrounded by the pixel electrode 191 and the common electrode 270. The common electrode 270 is formed in the row direction and is disposed on the microcavity 305 and at the second valley V2. The common electrode 270 is formed to contact the upper surface and the side of the microcavity 305. A width and an area of the microcavity 305 may be variously modified according to a size and resolution of the display device.

The common electrode 270 is formed to have a step shape at an edge of the microcavity 305. The common electrode 270 covers a side surface of the microcavity 305, and a portion thereof covering the side surface of the microcavity 305 is formed to have the step shape. The common electrode 270 covers an edge side surface of the microcavity 305, which is adjacent to the second valley V2. Accordingly, a portion of the common electrode 270 which is adjacent to the second valley V2 is formed to have the step shape.

In each pixel PX, the common electrode 270 is formed to be separated from the substrate 110, thereby forming the microcavity 305, but in the second valley V2, the common electrode 270 is formed to be attached on the substrate 110. In the second valley V2, the common electrode 270 is formed immediately above the second insulating layer 250. No space or metal layer is formed between the second insulating layer 250 and the common electrode 270

The common electrode 270 may be formed of a transparent metal material such as indium-tin oxide (ITO) and indium-zinc oxide (IZO). A predetermined voltage may be applied to the common electrode 270, and an electric field may be formed between the pixel electrode 191 and the common electrode 270.

A first alignment layer 11 is formed on the pixel electrode 191. The first alignment layer 11 may also be formed right on the first insulating layer 240 which is not covered by the pixel electrode 191.

A second alignment layer 21 is formed under the common electrode 270 so as to face the first alignment layer 11.

The first alignment layer 11 and the second alignment layer 21 may be formed as vertical alignment layers, and may be formed of an alignment material such as polyamic acid, polysiloxane, and polyimide. The first and second alignment layers 11 and 21 may be connected on a side wall of the edge of the microcavity 305.

A liquid crystal layer formed of liquid crystal molecules 310 is formed in the microcavity 305 positioned between the pixel electrode 191 and the common electrode 270. The liquid crystal molecules 310 have negative dielectric anisotropy, and may be erected in a vertical direction on the substrate 110 in a state where an electric field is not applied. That is, vertical alignment may be implemented.

The first sub-pixel electrode 191h and the second sub-pixel electrode 191l, to which the data voltage is applied, generate an electric field together with the common electrode 270 to determine a direction of the liquid crystal molecules 310 positioned in the microcavity 305 between the two electrodes 191 and 270. Luminance of light passing through the liquid crystal layer is changed according to the thusly determined direction of the liquid crystal molecules 310.

A third insulating layer 350 may be further formed on the common electrode 270. The third insulating layer 350 is formed on the common electrode 270, and the edge of the common electrode 270 is formed to have the step shape, so an edge of the third insulating layer 350 may be formed to have the step shape. A portion of the third insulating layer 350 which is adjacent to the second valley V2 is formed to have the step shape.

The third insulating layer 350 may be formed of an inorganic insulating material, such as a silicon nitride (SiNx) and a silicon oxide (SiOx), and may be omitted if necessary.

The roof layer 360 is formed on the third insulating layer 350. The roof layer 360 may be formed of an organic material. The microcavity 305 is formed under the roof layer 360, and the roof layer 360 may be hardened by a hardening process to maintain the shape of the microcavity 305. The roof layer 360 is formed in the row direction and is disposed on the microcavity 305 and at the second valley V2. The roof layer 360 may have substantially the same plane shape as the common electrode 270. The roof layer 360 may be hardened by a hardening process to maintain the shape of the microcavity 305. That is, the roof layer 360 is formed to be spaced apart from the pixel electrode 191 with the microcavity 305 interposed therebetween.

The common electrode 270 and the roof layer 360 are formed to expose the side surface of the edge of the microcavity 305, and portions where the microcavity 305 is not covered by the common electrode 270 and the roof layer 360 are injection holes 307a and 307b. The injection holes 307a and 307b include a first injection hole 307a, that extends to and through which a lateral surface of a first edge of the microcavity 305 is exposed, and a second injection hole 307b, that extends to and through which a lateral surface of a second edge of the microcavity 305 is exposed. The first edge and the second edge are edges facing each other, and for example, in the plane view, the first edge may be an upper edge of the microcavity 305, and the second edge may be a lower edge of the microcavity 305. The injection holes 307a and 307b extend to and expose side surfaces of the edges of the microcavity 305, which are adjacent to the first valley V1. The microcavities 305 are exposed by the injection holes 307a and 307b, so that an alignment solution, a liquid crystal material, or the like may be injected into the microcavities 305 through the injection holes 307a and 307b.

A fourth insulating layer 370 may be further formed on the roof layer 360. The fourth insulating layer 370 may be made of an inorganic insulating material such as a silicon nitride (SiNx) and a silicon oxide (SiOx). The fourth insulating layer 370 may be formed to cover the top and the side of the roof layer 360. The fourth insulating layer 370 serves to protect the roof layer 360 made of an organic material, and may be omitted if necessary.

An encapsulation layer 390 may be formed on the fourth insulating layer 370. The encapsulation layer 390 is formed to cover the injection hole 307 where a part of the microcavity 305 is exposed to the outside. That is, the encapsulation layer 390 may seal the microcavity 305 so that the liquid crystal molecules 310 formed in the microcavity 305 are not discharged to the outside. The encapsulation layer 390 contacts the liquid crystal molecules 310, and as a result, the encapsulation layer 390 may be made of a material which does not react with the liquid crystal molecules 310. For example, the encapsulation layer 390 may be made of parylene and the like.

The encapsulation layer 390 may be formed by a multilayer such as a double layer and a triple layer. The double layer is configured by two layers made of different materials. The triple layer is configured by three layers, and materials of adjacent layers are different from each other. For example, the encapsulation layer 390 may include a layer made of an organic insulating material or a layer made of an inorganic insulating material.

Although not illustrated, polarizers may be further formed on the upper and lower sides of the display device. The polarizers may be configured by a first polarizer and a second polarizer. The first polarizer may be attached onto the lower side of the substrate 110, and the second polarizer may be attached onto the encapsulation layer 390.

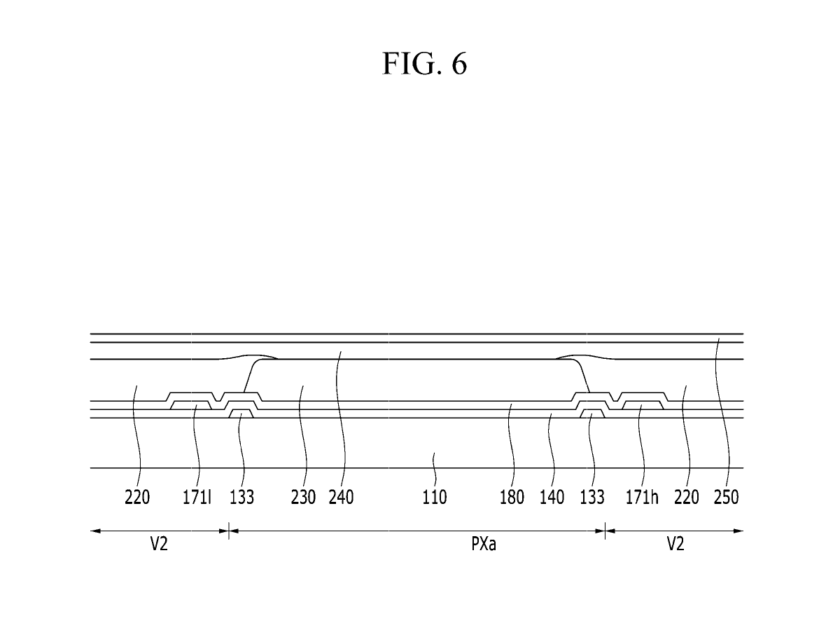

Next, a manufacturing method of the display device in accordance with the exemplary embodiment will be described with reference to FIG. 6 to FIG. 13. The manufacturing method will also be described by referring to FIG. 1 to FIG. 5.

FIG. 6 to FIG. 13 are stepwise cross-sectional views illustrating a manufacturing method of the display device in accordance with the exemplary embodiment.

First, as shown in FIG. 6, a gate line 121 extending in a first direction, and a first gate electrode 124h and a second gate electrode 124l protruding from the gate line 121, are formed on a substrate 110 made of glass or plastic. The first gate electrode 124h and the second gate electrode 124l are connected to each other, thereby forming one protrusion.

Further, a storage electrode line 131 separated from the gate line 121 and storage electrodes 133 and 135 protruding from the storage electrode line 131 may be formed together. The storage electrode line 131 extends parallel to the gate line 121. The storage electrode 133 protruding above the storage electrode line 131 may be formed to surround an edge of a first subpixel PXa, and the storage electrode 135 protruding below the storage electrode line 131 may be formed to be adjacent to the first gate electrode 124h and the second gate electrode 124l.

Next, a gate insulating layer 140 is formed on the gate line 121, the first gate electrode 124h, the second gate electrode 124l, the storage electrode line 131, and the storage electrodes 133 and 135 by using an inorganic insulating material such as a silicon oxide (SiOx) or a silicon nitride (SiNx). The gate insulating layer 140 may be formed as a single layer or a multiple layer.

Next, a first semiconductor 154h and a second semiconductor 154l are formed by depositing and then patterning a semiconductor material such as amorphous silicon, polycrystalline silicon, and a metal oxide on the gate insulating layer 140. The first semiconductor 154h may be formed to be positioned on the first gate electrode 124h, and the second semiconductor 154l may be formed to be positioned on the second gate electrode 124l.

Next, a first data line 171h and a second data line 171l extending in the second direction are formed by depositing and then patterning a metal material. The metal material may be formed as a single layer or a multiple layer.

Further, a first source electrode 173h protruding above the first gate electrode 124h from the first data line 171h and a first drain electrode 175h spaced apart from the first source electrode 173h are formed together. In addition, a second source electrode 173l protruding above the second gate electrode 124l from the second data line 171l and a second drain electrode 175l spaced apart from the second source electrode 173l are formed together.

The first and second semiconductors 154h and 154l, the first and second data lines 171h and 171l, the first and second source electrodes 173h and 173l, and the first and second drain electrodes 175h and 175l may be formed by sequentially depositing and then simultaneously patterning a semiconductor material and a metal material. In this case, the first semiconductor 154h is formed below the first data line 171h, and the second semiconductor 154l is formed below the second data line 171l.

The first and second gate electrodes 124h and 124l, the first and second source electrodes 173h and 173l, and the first and second drain electrodes 175h and 175l form first and second thin film transistors (TFTs) Qh and Ql together with the first and second semiconductors 154h and 154l, respectively.

Next, a passivation layer 180 is formed on the first data line 171h, the second data line 171l, the first source electrode 173h, the first drain electrode 175h, the first semiconductor 154h exposed between the first source electrode 173h and the first drain electrode 175h, the second source electrode 173l, the second drain electrode 175l, and the second semiconductor 154l exposed between the second source electrode 173l and the second drain electrode 175l. The passivation layer 180 may be made of an organic insulating material or an inorganic insulating material, and may be formed as a single layer or a multiple layer.

A color filter 230 is then formed on the passivation layer 180. The color filter 230 may be formed within the first subpixel PXa and the second subpixel PXb, and may not be formed at the first valley V1. Color filters 230 of the same color may be formed according to the column direction of the plurality of pixels PX. For example, when forming the color filter 230 of three colors, the first color filter 230 is formed and then the color filter 230 of the second color filter 230 is formed by shifting a mask. Next, after forming the second color filter 230, the third color filter 230 may be formed by shifting the mask.

Next, the boundary of each pixel PX and the light blocking member 220 are respectively formed on the passivation layer 180 and the thin film transistor.

As described above, it has been described that the light blocking member 220 is formed after the color filter 230 is formed, but it is not limited thereto. Alternatively, the color filter 230 is formed after the light blocking member 220 is formed.

Next, the first insulating layer 240 may be further formed on the color filter 230 and the light blocking member 220 by using an organic insulating material, and the second insulating layer 250 is formed on the first insulating layer 240 by using an inorganic insulating material.

The passivation layer 180, the first insulating layer 240, and the second insulating layer 250 are patterned to form a first contact hole 181h extending to and exposing at least a portion of the first drain electrode 175h and a second contact hole 181 extending to and exposing at least a portion of the second drain electrode 175l. In this case, the passivation layer 180, the first insulating layer 240, and the second insulating layer 250 may be simultaneously patterned, may be separately patterned, or may be partially and simultaneously patterned.

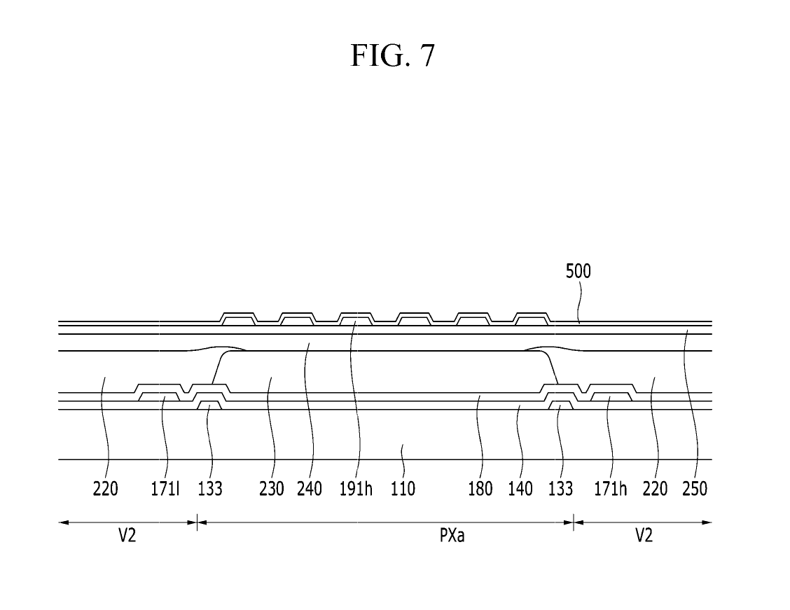

As shown in FIG. 7, the transparent metal material such as ITO or IZO is deposited and patterned on the second insulating layer 250 to form a pixel electrode 191 in the pixel PX. The pixel electrode 191 includes a first subpixel electrode 191h positioned in the first subpixel PXa, and a second subpixel electrode 191l positioned in the second subpixel PXb. The first subpixel electrode 191h and the second subpixel electrode 191l are separated from each other with a first valley V1 therebetween.

Horizontal stem portions 193h and 193l and vertical stem portions 192h and 192l crossing the horizontal stem portions 193h and 193l are formed in the first subpixel electrode 191h and the second subpixel electrode 191l, respectively. Further, a plurality of minute branches 194h and 194l, which obliquely extend from the horizontal stem portions 193h and 193l and the vertical stem portions 192h and 192l, are formed.

Next, a first barrier layer 500 is formed by depositing a metal material on the pixel electrode 191. For example, the first barrier layer 500 may be made of copper. The first barrier layer 500 may be made of a material different from that of the pixel electrode 191 and the common electrode 270.

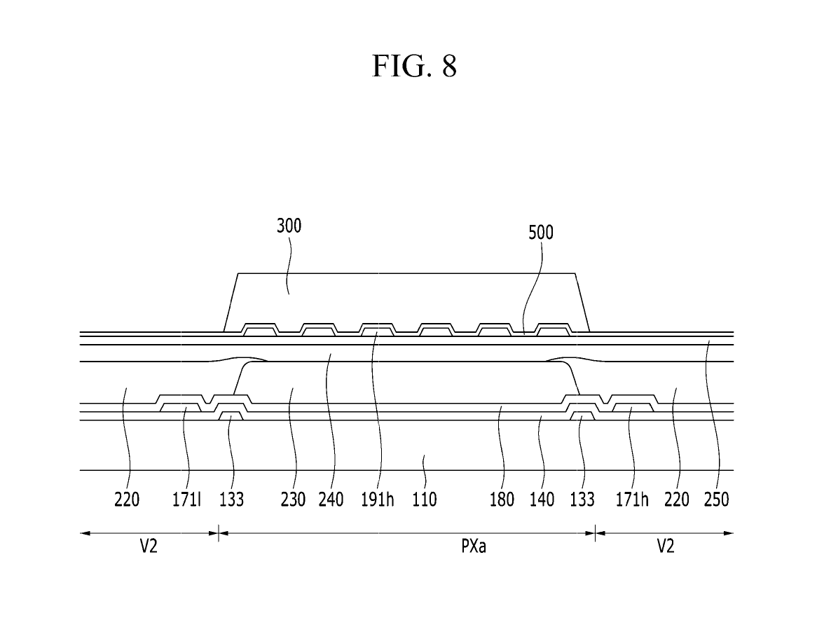

As shown in FIG. 8, a sacrificial layer 300 is formed by coating a photosensitive organic material on the first barrier layer 500 and performing a photolithography process thereon. The sacrificial layer 300 may be formed in the column direction. The sacrificial layer 300 may be formed at each pixel PX and the first valley V1, and may not be formed at the second valley V2.

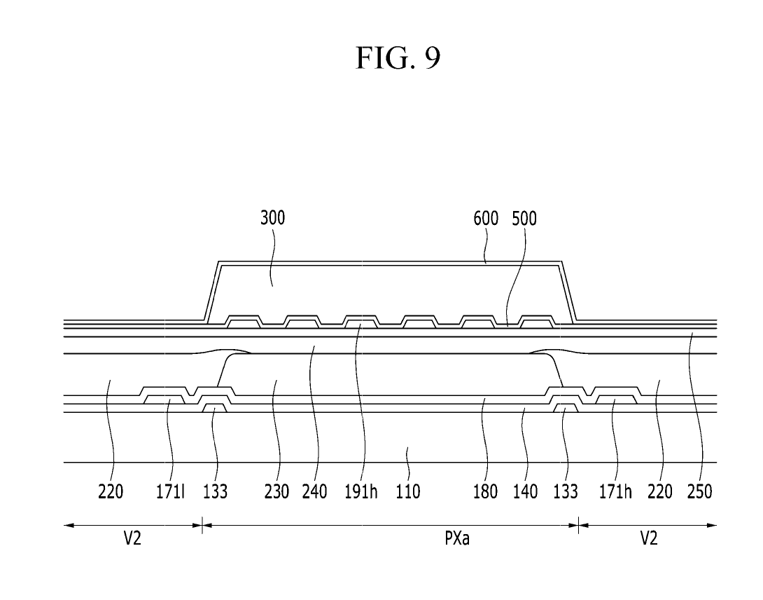

As shown in FIG. 9, a second barrier layer 600 is formed by depositing a metal material on the sacrificial layer 300. For example, the second barrier layer 600 may be made of copper. The second barrier layer 600 may be made of a material different from that of the pixel electrode 191 and the common electrode 270. The first barrier layer 500 and the second barrier layer 600 may be made of the same material.

The first barrier layer 500 is formed before the sacrificial layer 300 is formed, and the second barrier layer 600 is formed after the sacrificial layer 300 is formed. Accordingly, the sacrificial layer 300 is surrounded by the first barrier layer 500 and the second barrier layer 600. The first barrier layer 500 is formed below a bottom surface of the sacrificial layer 300, and the second barrier layer 600 is formed to cover a top surface and a side surface of the sacrificial layer 300.

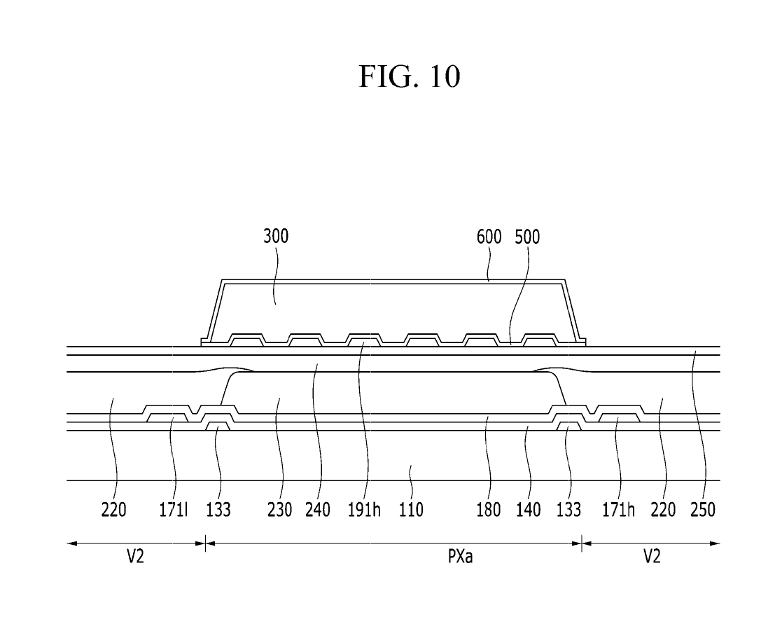

As shown in FIG. 10, portions of the first barrier layer 500 and the second barrier layer 600 which are located at the second valley V2 are removed by patterning thereof.

In the patterning of the first barrier layer 500 and the second barrier layer 600, a process margin may be predetermined such that a portion of the second barrier layer 600 covering the sacrificial layer 300 is not removed. Accordingly, a portion at which the first barrier layer 500 and the second barrier layer 600 are overlapped with each other remains. The remaining portion, adjacent to the second valley V2, at which the first barrier layer 500 and the second barrier layer 600 are overlapped with each other is formed to have the step shape.

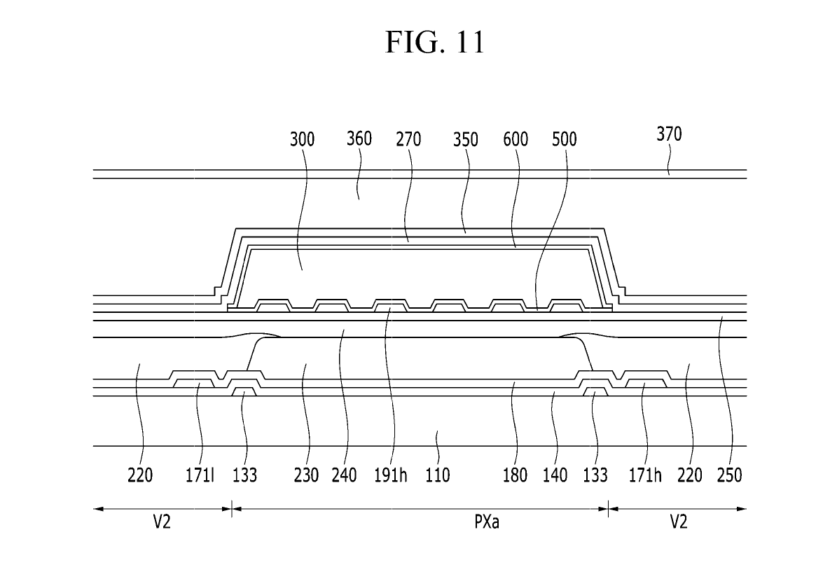

As shown in FIG. 11, the common electrode 270 is formed by depositing a transparent metal material such as indium tin oxide (ITO) or indium zinc oxide (IZO) on the second barrier layer 600.

The common electrode 270 is located on the first barrier layer 500 and the second barrier layer 600, and the portions of the first barrier layer 500 and the second barrier layer 600 which are adjacent to the second valley V2 are formed to have the step shape. Accordingly, a portion of the common electrode 270 which is adjacent to the second valley V2 is formed to have the step shape.

The common electrode 270 is located immediately on the second insulating layer 250 since the portions of the first barrier layer 500 and the second barrier layer 600 which are located at the second valley V2 are removed.

Next, the third insulating layer 350 of the inorganic insulating material such as a silicon oxide or a silicon nitride is formed on the common electrode 270. The third insulating layer 350 is located on the common electrode 270, and the portion of the common electrode 270 which is adjacent to the second valley V2 is formed to have the step shape. Accordingly, a portion of the third insulating layer 350 which adjacent to the second valley V2 is also formed to have the step portion.

Next, the roof layer 360 is formed by coating an organic material on the third insulating layer 350. In this case, the patterning may be performed to remove a portion of the organic material which is positioned at the first valley V1. Accordingly, the roof layer 360 is formed in such a shape so as that the roof layer 360 is connected along a plurality of pixel rows.

The third insulating layer 350 and the common electrode 270 are then patterned by using the roof layer 360 as a mask to remove the portions of the third insulating layer 350 and the common electrode 270 which are positioned at the first valley V1.

Next, the fourth insulating layer 370 may be formed on the roof layer 360 by using an inorganic insulating material such as a silicon nitride (SiNx) and a silicon oxide (SiOx). The fourth insulating layer 370 is patterned to remove a portion of the fourth insulating layer 370 which is positioned at the first valley V1. In this case, the fourth insulating layer 370 may be formed to cover a top surface and a side surface of the roof layer 360.

The portion of the sacrificial layer 300 which is positioned at the first valley V1 is exposed to the outside by patterning the roof layer 360, the third insulating layer 350, the common electrode 270, and the fourth insulating layer 370.

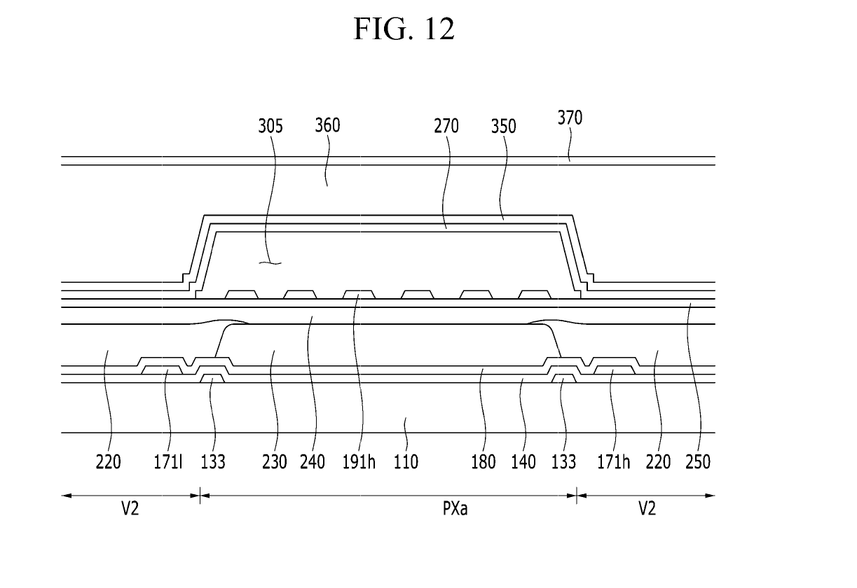

As shown in FIG. 12, the sacrificial layer 300 is fully removed by applying a developer or a stripper solution on the substrate 110 where the sacrificial layer 300 is exposed, or the sacrificial layer 300 is fully removed by using an ashing process.

When the sacrificial layer 300 is removed, the microcavity 305 is generated at a portion where the sacrificial layer 300 is positioned.

Next, the first barrier layer 500 and the second barrier layer 600 are removed by supplying an etchant to the substrate 110 where the sacrificial layer 300 has been removed. Specifically, the etchant is injected into the microcavity 305 to remove a portion of the first barrier layer 500 which is located on the bottom surface of the microcavity 305 and a portion of the second barrier layer 600 which covers the top surface and the side surface of the microcavity 305.

In the meantime, as a plurality of processes are added after the sacrificial layer 300 is formed, the characteristic of the sacrificial layer 300 may be changed, thereby deforming films. Such deformed films may be generated between the sacrificial layer 300 and the first barrier layer 500, and/or between the sacrificial layer 300 and the second barrier layer 600. The deformed films may not be removed in the process of removing the sacrificial layer 300, and thus may maintain the top surface of the first barrier layer 500 and the bottom surface of the second barrier layer 600. However, in the present exemplary embodiment, the deformed films can be removed in the process of removing the first barrier layer 500 and the second barrier layer 600

Accordingly, problems such as defective aligning agent coating, defective liquid crystal injection, and the like caused by the deformed films can be solved.

It is preferable that the pixel electrode 191 and the common electrode 270 are not damaged in the process of removing the first barrier layer 500 and the second barrier layer 600. Accordingly, the first barrier layer 500 and the second barrier layer 600 may be removed by using a wet etching process to improve etch selectivity. The material of the first barrier layer 500 and the second barrier layer 600 may be selected such that a material of the etchant for etching the first barrier layer 500 and the second barrier layer 600 is different from that of the etchant for etching the pixel electrode 191 and the common electrode 270. For example, the first barrier layer 500 and the second barrier layer 600 may be formed of copper. Alternatively, if the same etchant is used, materials having different etch rates may be used. For example, the first barrier layer 500 and the second barrier layer 600 may be made of a material having an etch rate that is quicker than that of the material of the pixel electrode 191 and the common electrode 270.

As described above, the portions of the first barrier layer 500 and the second barrier layer 600 which are located at the second valley V2 are removed in the process of patterning the first barrier layer 500 and the second barrier layer 600. If the common electrode 270 is formed on the second barrier layer 600 in the second valley V2 without patterning the first barrier layer 500 and the second barrier layer 600, the common electrode 270 may be separated from the substrate 110 in the process of removing the first barrier layer 500 and the second barrier layer 600. In the present exemplary embodiment, it is possible to prevent a lifting phenomenon of the roof layer 360 by forming the common electrode 270 directly on the second insulating layer 250.

In the meantime, it is preferable that the first barrier layer 500 and the second barrier layer 600 are formed to have thickness that is thinner than those of the pixel electrode 191 and the common electrode 270 to easily remove the first barrier layer 500 and the second barrier layer 600.

The common electrode 270 and the pixel electrode 191 are spaced apart from each other with the microcavity 305 therebetween. The pixel electrode 191 and the roof layer 360 are spaced apart from each other with the microcavity 305 therebetween.

The common electrode 270 and the roof layer 360 are formed to cover the upper surface and both side surfaces of the microcavity 305.

The microcavity 305 is exposed to the outside through portions where the roof layer 360 and the common electrode 270 are removed, which are injection holes 307a and 307b. Two injection holes 307a and 307b may be formed in one microcavity 305, for example, a first injection hole 307a through which a lateral surface of a first edge of the microcavity 305 is exposed, and a second injection hole 307b through which a lateral surface of a second edge of the microcavity 305 is exposed, may be formed. The first edge and the second edge face each other, and for example, the first edge may be the upper edge of the microcavity 305, and the second edge may be the lower edge of the microcavity 305. The injection holes 307a and 307b expose side surfaces of the edges of the microcavity 305, which are adjacent to the first valley V1.

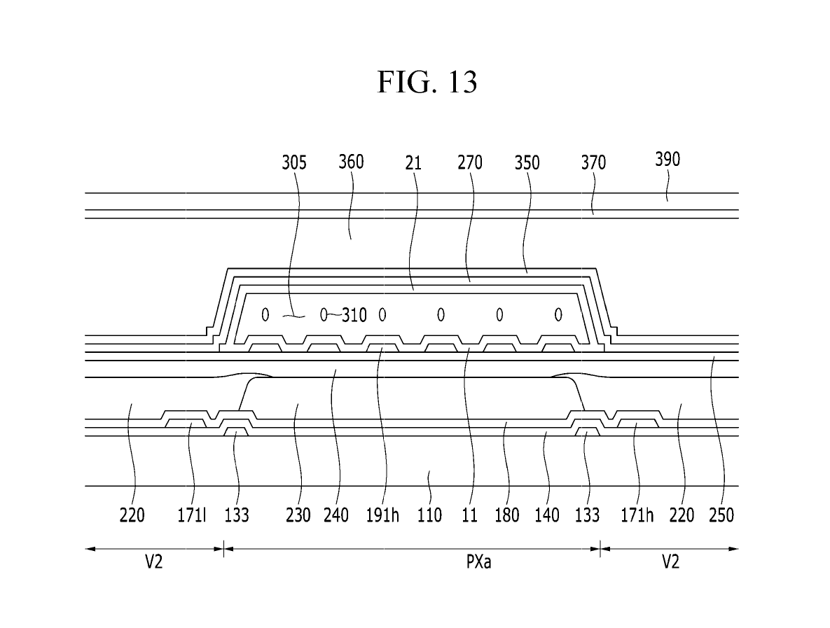

As shown in FIG. 13, when an aligning agent containing an alignment material is dripped on the substrate 110 by a spin coating method or an inkjet method, the aligning agent is injected into the microcavity 305 through the injection holes 307a and 307b. When the aligning agent is injected into the microcavity 305 and then a curing process is performed, a solution component is evaporated and the alignment material remains at an inner wall of the microcavity 305.

Accordingly, a first alignment layer 11 may be formed on the pixel electrode 191, and a second alignment layer 21 may be formed below the common electrode 270. The first alignment layer 11 and the second alignment layer 21 are formed to face each other with the microcavity 305 therebetween, and to be connected to each other at the side wall of the edge of the microcavity 305.

In this case, the first and second alignment layers 11 and 21 may be aligned in a direction perpendicular to the substrate 110 except at the lateral surface of the microcavity 305.

Subsequently, when a liquid crystal material including the liquid crystal molecules 310 is dripped on the substrate 110 by an inkjet method or a dispensing method, the liquid crystal material is injected into the microcavity 305 through the injection holes 307a and 307b.

The encapsulation layer 390 is then formed by depositing a material which does not react with the liquid crystal molecules 310 on the fourth insulating layer 370. The encapsulation layer 390 is formed to cover the injection holes 307a and 307b, thereby sealing the microcavity 305 so that the liquid crystal molecules 310 formed in the microcavity 305 are not discharged to the outside.

Next, although not illustrated, polarizers may be further attached onto the upper and lower surfaces of the display device. The polarizers may include a first polarizer and a second polarizer. The first polarizer may be attached onto the lower surface of the substrate 110, and the second polarizer may be attached onto the encapsulation layer 390.

While the inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

<Description of Symbols>

| | |
|---|---|
| 11: first alignment layer | 21: second alignment layer |
| 110: substrate | 121: gate line |
| 171h: first data line | 171l: second data line |
| 191h: first subpixel electrode | 191l: second subpixel electrode |
| 220: light blocking member | 230: color filter |
| 270: common electrode | 300: sacrificial layer |
| 305: microcavity | 307a, 307b: injection holes |
| 310: liquid crystal molecule | 360: roof layer |
| 500: first barrier layer | 600: second barrier layer |

What is claimed is:

1. A display device comprising:
a substrate;
a thin film transistor on the substrate;
a pixel electrode connected to the thin film transistor;
a common electrode on the pixel electrode to be spaced apart from the pixel electrode with a plurality of microcavities comprising a microcavity interposed therebetween;
a roof layer on the common electrode;
a liquid crystal layer filling the microcavity; and
an encapsulation layer on the roof layer to seal the microcavity,
wherein the common electrode positioned at an edge of the microcavity has a step shape.

2. The display device of claim 1, wherein the common electrode covers a top surface and a side surface of the microcavity, and
a portion of the common electrode which covers the side surface of the microcavity has a step shape.

3. The display device of claim 1, wherein the microcavities are disposed in a matrix shape, and
the display device further comprises:
a first valley positioned between microcavities adjacent to each other in a column direction; and
a second valley positioned between microcavities adjacent to each other in a row direction.

4. The display device of claim 3, wherein the common electrode is further on the second valley.

5. The display device of claim 4, wherein a portion of the common electrode which is adjacent to the second valley is in a step shape.

6. The display device of claim 5, further comprising:
an insulating layer on the thin film transistor,
wherein the common electrode is immediately on the insulating layer in the second valley.

7. A manufacturing method of a display device, the method comprising:
forming a thin film transistor on a substrate;
forming a pixel electrode connected to the thin film transistor;
forming a first barrier layer on the pixel electrode;
forming a sacrificial layer on the first barrier layer;
forming a second barrier layer on the sacrificial layer;
forming a common electrode on the sacrificial layer;
forming a roof layer on the common electrode;
patterning the common electrode and the roof layer to expose a portion of the sacrificial layer;
removing the sacrificial layer to form a microcavity between the pixel electrode and the common electrode;
removing the first barrier layer and the second barrier layer;
injecting a liquid crystal material inside the microcavity to form a liquid crystal layer; and
forming an encapsulation layer to cover a portion where the microcavity is exposed to seal the microcavity.

8. The manufacturing method of claim 7, wherein a plurality of microcavities including the microcavity are disposed in a matrix shape,
a first valley is positioned between microcavities adjacent to each other in a column direction, and
a second valley is positioned between microcavities adjacent to each other in a row direction.

9. The manufacturing method of claim 8, further comprising
patterning the first barrier layer and the second barrier layer after the second barrier layer is formed.

10. The manufacturing method of claim 9, wherein portions of the first barrier layer and the second barrier layer, which are positioned at the second valley, are removed in the patterning of the first barrier layer and the second barrier layer.

11. The manufacturing method of claim 10, wherein the common electrode is further formed on the second valley.

12. The manufacturing method of claim 11, wherein a portion of the common electrode which is adjacent to the second valley is formed in a step shape.

13. The manufacturing method of claim 12, further comprising
forming an insulating layer on the thin film transistor,
wherein the common electrode is formed immediately on the insulating layer in the second valley.

14. The manufacturing method of claim 7, wherein the common electrode covers a top surface and a side surface of the microcavity, and
a portion of the common electrode which covers the side surface of the microcavity is formed to have a step shape.

15. The manufacturing method of claim 7, wherein the first barrier layer and the second barrier layer are removed by using a wet etching method in the removing of the first barrier layer and the second barrier layer.

16. The manufacturing method of claim 15, wherein the pixel electrode and the common electrode are not removed in the process of removing the first barrier layer and the second barrier layer.

17. The manufacturing method of claim 7, wherein each of the first barrier layer and the second barrier layer includes copper.

18. The manufacturing method of claim 17, wherein each of the pixel electrode and the common electrode includes indium tin oxide (ITO) or indium zinc oxide (IZO).

19. The manufacturing method of claim 7, wherein the first barrier layer is formed to have a thickness that is thinner than that of the pixel electrode.

20. The manufacturing method of claim 7, wherein the second barrier layer is formed to have a thickness that is thinner than that of the common electrode.
